(19) United States
(12) Patent Application Publication
(10) Pub. No.: US 2025/0300605 A1
(43) Pub. Date: Sep. 25, 2025

(54) TRANSIMPEDANCE AMPLIFIER WITH VIRTUAL GROUND SHUNT RESISTOR

(71) Applicant: QUALCOMM Incorporated, San Diego, CA (US)

(72) Inventors: Qingrui MENG, San Diego, CA (US); Bharadvaj BHAMIDIPATI, San Diego, CA (US); Joseph DUNCAN, Carlsbad, CA (US)

(21) Appl. No.: 18/610,760

(22) Filed: Mar. 20, 2024

(51) Int. Cl. H03F 1/08; H03F 3/45

(52) U.S. Cl. CPC H03F 1/08; H03F 3/45475; H03F 2200/102; H03F 2200/129; H03F 2200/451

(57) ABSTRACT

Methods and apparatus for amplifying a signal via an amplification circuit are described. An example amplification circuit generally includes an amplifier including an inverting input configured to receive a signal for wireless transmission. The amplification circuit also includes an impedance coupled between the inverting input and an output of the amplifier. The amplification circuit further includes a resistive element including (i) a first terminal coupled to the inverting input and (ii) a second terminal coupled to a reference potential node for the amplification circuit.

### TECHNICAL FIELD

Certain aspects of the present disclosure generally relate to electronic circuits and, more particularly, to transimpedance amplifiers and circuits using such amplifiers.

### BACKGROUND

Wireless communication devices are widely deployed to provide various communication services such as telephony, video, data, messaging, broadcasts, and so on. Such wireless communication devices may transmit and/or receive radio frequency (RF) signals via any of various suitable radio access technologies (RATs) including, but not limited to, 5G New Radio (NR), Long Term Evolution (LTE), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., WiFi), and the like.

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station.

Amplifiers (e.g., transimpedance amplifiers, inverting amplifiers, etc.) may be used in a variety of systems to increase the power of an input signal, such as in wireless communication systems utilizing radio frequency (RF) signals. For example, amplifiers may be used in wireless communication systems to increase the power of an RF signal for transmission, or increase the power of a received RF signal. RF front ends in such systems may implement envelope tracking, which is an approach to amplifier design where the power supply voltage to the amplifier is adjusted to track the instant transmission power demanded for transmitting a dynamic signal. Accordingly, the amplifier may operate efficiently according to the varying power level.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include improved performance of transimpedance amplifiers.

Certain aspects of the present disclosure provide an amplification circuit. The amplification circuit generally includes an amplifier including an inverting input configured to receive a signal. The amplification circuit also includes an impedance coupled between the inverting input and an output of the amplifier. The amplification circuit further includes a resistive element including (i) a first terminal coupled to the inverting input and (ii) a second terminal coupled to a reference potential node for the amplification circuit.

Certain aspects of the present disclosure provide a wireless device. The wireless device includes an amplification circuit. The amplification circuit includes a first amplifier including an inverting input configured to receive a signal. The amplification circuit also includes an impedance coupled between the inverting input and an output of the first amplifier. The amplification circuit further includes a resistive element including (i) a first terminal coupled to the inverting input and (ii) a second terminal coupled to a reference potential node for the amplification circuit. The wireless device also includes a second amplifier including a first power supply node coupled to an output of the amplification circuit.

Certain aspects of the present disclosure provide a method of wireless communication. The method generally includes amplifying an input signal via an amplification circuit to generate an amplified signal. The amplification circuit includes (i) an amplifier including an inverting input configured to receive the input signal; (ii) an impedance coupled between the inverting input and an output of the amplifier; and (iii) a resistive element including a first terminal coupled to the inverting input and including a second terminal coupled to a reference potential node for the amplification circuit. The method also includes outputting the amplified signal.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in which aspects of the present disclosure may be practiced.

FIG. 2 is a block diagram conceptually illustrating a design of an example a base station (BS) and user equipment (UE), in which aspects of the present disclosure may be practiced.

FIG. 3 is a block diagram of an example radio frequency (RF) transceiver, in which aspects of the present disclosure may be practiced.

FIG. 4 illustrates an example envelope tracking amplification system, in which aspects of the present disclosure may be practiced.

FIG. 5 illustrates an example amplification circuit, in accordance with certain aspects of the present disclosure.

FIG. 6 illustrates another example amplification circuit, in accordance with certain aspects of the present disclosure.

FIG. 7 is a flow diagram of example operations for amplifying a signal, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure generally relate to electronic components and, more particularly, to an amplification circuit that includes an amplifier (e.g., a transimpedance amplifier) and a shunt resistive element coupled between an inverting input of the amplifier (e.g., virtual ground) and a reference potential node (e.g., electrical ground) for the amplification circuit. In certain aspects described herein, the amplification circuit may also include a current source that is coupled between the shunt resistive element and a power supply node for the amplification circuit. In other aspects described herein, the amplification circuit may also include a capacitive element coupled in series with the shunt resistive element. The amplification circuit described herein may improve stability and/or linearity of the amplifier, relative to conventional amplification circuits implemented without a shunt resistive element, as described further herein.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Wireless System

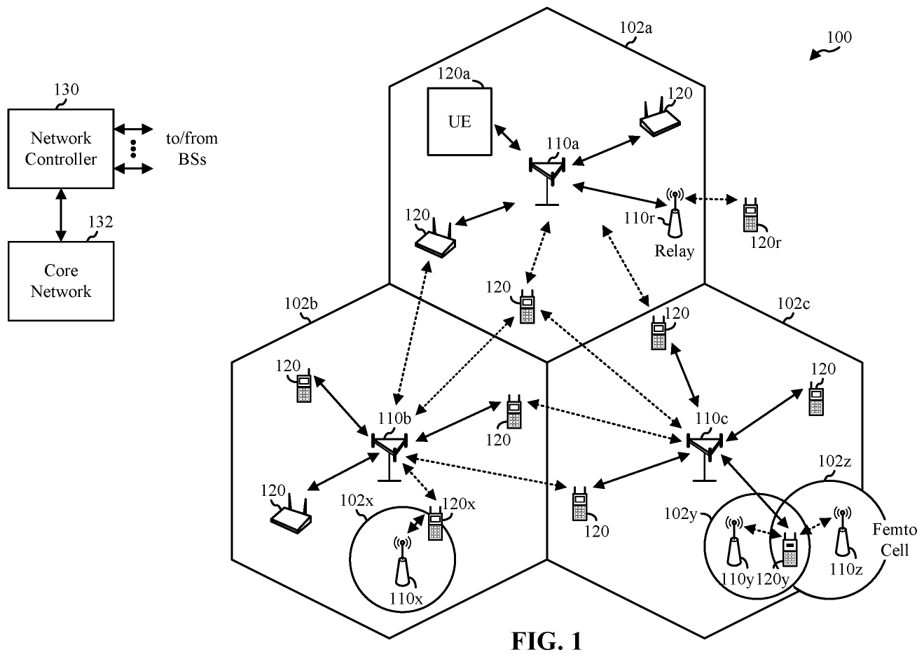

FIG. 1 illustrates an example wireless communications network 100, in which aspects of the present disclosure may be practiced. For example, the wireless communications network 100 may be a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation/Third Generation (2G/3G) network), or a code division multiple access (CDMA) system (e.g., a 2G/3G network), or may be configured for communications according to an Institute of Electrical and Electronics Engineers (IEEE) standard such as one or more of the 802.11 standards, etc.

As illustrated in FIG. 1, the wireless communications network 100 may include a number of base stations (BSs) 110a-z (each also individually referred to herein as “BS 110” or collectively as “BSs 110”) and other network entities. A BS may also be referred to as an access point (AP), an evolved Node B (NB) (eNodeB or eNB), a next generation Node B (gNodeB or gNB), or some other terminology.

A BS 110 may provide communication coverage for a particular geographic area, sometimes referred to as a “cell,” which may be stationary or may move according to the location of a mobile BS. In some examples, the BSs 110 may be interconnected to one another and/or to one or more other BSs or network nodes (not shown) in wireless communications network 100 through various types of backhaul interfaces (e.g., a direct physical connection, a wireless connection, a virtual network, or the like) using any suitable transport network. In the example shown in FIG. 1, the BSs 110a, 110b, and 110c may be macro BSs for the macro cells 102a, 102b, and 102c, respectively. The BS 110x may be a pico BS for a pico cell 102x. The BSs 110y and 110z may be femto BSs for the femto cells 102y and 102z, respectively. A BS may support one or multiple cells.

The BSs 110 communicate with one or more user equipments (UEs) 120a-y (each also individually referred to herein as “UE 120” or collectively as “UEs 120”) in the wireless communications network 100. A UE may be fixed or mobile and may also be referred to as a user terminal (UT), a mobile station (MS), an access terminal, a station (STA), a client, a wireless device, a mobile device, or some other terminology. A user terminal may be a wireless device, such as a cellular phone, a smartphone, a personal digital assistant (PDA), a handheld device, a wearable device, a wireless modem, a laptop computer, a tablet, a personal computer, etc.

The BSs 110 are considered transmitting entities for the downlink and receiving entities for the uplink. The UEs 120 are considered transmitting entities for the uplink and receiving entities for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink. Nᵤₚ UEs may be selected for simultaneous transmission on the uplink, N_{dn} UEs may be selected for simultaneous transmission on the downlink. Nᵤₚ may or may not be equal to N_{dn}, and Nᵤₚ and N_{dn} may be static values or can change for each scheduling interval. Beam-steering or some other spatial processing technique may be used at the BSs 110 and/or UEs 120.

The UEs 120 (e.g., 120x, 120y, etc.) may be dispersed throughout the wireless communications network 100, and each UE 120 may be stationary or mobile. The wireless communications network 100 may also include relay stations (e.g., relay station 110r), also referred to as relays or the like, that receive a transmission of data and/or other information from an upstream station (e.g., a BS 110a or a UE 120r) and send a transmission of the data and/or other information to a downstream station (e.g., a UE 120 or a BS 110), or that relays transmissions between UEs 120, to facilitate communication between devices.

The BSs 110 may communicate with one or more UEs 120 at any given moment on the downlink and uplink. The downlink (i.e., forward link) is the communication link from the BSs 110 to the UEs 120, and the uplink (i.e., reverse link) is the communication link from the UEs 120 to the BSs 110. A UE 120 may also communicate peer-to-peer with another UE 120.

The wireless communications network 100 may use multiple transmit and multiple receive antennas for data transmission on the downlink and uplink. BSs 110 may be equipped with a number Nₐₚ of antennas to achieve transmit diversity for downlink transmissions and/or receive diversity for uplink transmissions. A set Nᵤ of UEs 120 may receive downlink transmissions and transmit uplink transmissions. Each UE 120 may transmit user-specific data to and/or receive user-specific data from the BSs 110. In general, each UE 120 may be equipped with one or multiple antennas. The Nᵤ UEs 120 can have the same or different numbers of antennas.

The wireless communications network 100 may be a time division duplex (TDD) system or a frequency division duplex (FDD) system. For a TDD system, the downlink and uplink share the same frequency band. For an FDD system, the downlink and uplink use different frequency bands. The wireless communications network 100 may also utilize a single carrier or multiple carriers for transmission. Each UE 120 may be equipped with a single antenna (e.g., to keep costs down) or multiple antennas (e.g., where the additional cost can be supported).

A network controller 130 (also sometimes referred to as a “system controller”) may be in communication with a set of BSs 110 and provide coordination and control for these BSs 110 (e.g., via a backhaul). In certain cases (e.g., in a 5G NR system), the network controller 130 may include a centralized unit (CU) and/or a distributed unit (DU). In certain aspects, the network controller 130 may be in communication with a core network 132 (e.g., a 5G Core Network (5GC)), which provides various network functions such as Access and Mobility Management, Session Management, User Plane Function, Policy Control Function, Authentication Server Function, Unified Data Management, Application Function, Network Exposure Function, Network Repository Function, Network Slice Selection Function, etc.

In certain aspects of the present disclosure, the BSs 110 and/or the UEs 120 may include a transceiver front end (TX/RX) (also known as a radio frequency front end (RFFE)), which includes an amplification circuit. The amplification circuit may include an amplifier and a shunt resistive element coupled between an inverting input of the amplifier (e.g., virtual ground) and a reference potential node (e.g., ground) for the amplification circuit.

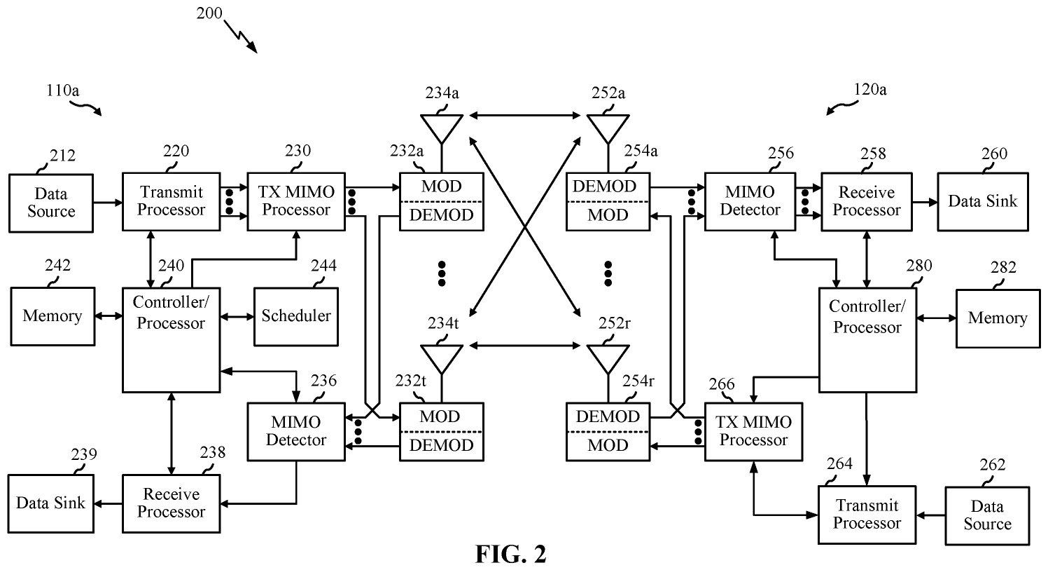

FIG. 2 illustrates example components of BS 110a and UE 120a (e.g., from the wireless communications network 100 of FIG. 1), in which aspects of the present disclosure may be implemented.

On the downlink, at the BS 110a, a transmit processor 220 may receive data from a data source 212, control information from a controller/processor 240, and/or possibly other data (e.g., from a scheduler 244). The various types of data may be sent on different transport channels. For example, the control information may be designated for the physical broadcast channel (PBCH), physical control format indicator channel (PCFICH), physical hybrid automatic repeat request (HARQ) indicator channel (PHICH), physical downlink control channel (PDCCH), group common PDCCH (GC PDCCH), etc. The data may be designated for the physical downlink shared channel (PDSCH), etc. A medium access control (MAC)-control element (MAC-CE) is a MAC layer communication structure that may be used for control command exchange between wireless nodes. The MAC-CE may be carried in a shared channel such as a PDSCH, a physical uplink shared channel (PUSCH), or a physical sidelink shared channel (PSSCH).

The processor 220 may process (e.g., encode and symbol map) the data and control information to obtain data symbols and control symbols, respectively. The transmit processor 220 may also generate reference symbols, such as for the primary synchronization signal (PSS), secondary synchronization signal (SSS), PBCH demodulation reference signal (DMRS), and channel state information reference signal (CSI-RS).

A transmit (TX) multiple-input, multiple-output (MIMO) processor 230 may perform spatial processing (e.g., precoding) on the data symbols, the control symbols, and/or the reference symbols, if applicable, and may provide output symbol streams to the modulators (MODs) in transceivers 232a-232t. Each modulator in transceivers 232a-232t may process a respective output symbol stream (e.g., for orthogonal frequency division multiplexing (OFDM), etc.) to obtain an output sample stream. Each of the transceivers 232a-232t may further process (e.g., convert to analog, amplify, filter, and upconvert) the output sample stream to obtain a downlink signal. Downlink signals from the transceivers 232a-232t may be transmitted via the antennas 234a-234t, respectively.

At the UE 120a, the antennas 252a-252r may receive the downlink signals from the BS 110a and may provide received signals to the transceivers 254a-254r, respectively. The transceivers 254a-254r may condition (e.g., filter, amplify, downconvert, and digitize) a respective received signal to obtain input samples. Each demodulator (DEMOD) in the transceivers 232a-232t may further process the input samples (e.g., for OFDM, etc.) to obtain received symbols. A MIMO detector 256 may obtain received symbols from all the demodulators in transceivers 254a-254r, perform MIMO detection on the received symbols if applicable, and provide detected symbols. A receive processor 258 may process (e.g., demodulate, deinterleave, and decode) the detected symbols, provide decoded data for the UE 120a to a data sink 260, and provide decoded control information to a controller/processor 280.

On the uplink, at UE 120a, a transmit processor 264 may receive and process data (e.g., for the physical uplink shared channel (PUSCH)) from a data source 262 and control information (e.g., for the physical uplink control channel (PUCCH)) from the controller/processor 280. The transmit processor 264 may also generate reference symbols for a reference signal (e.g., the sounding reference signal (SRS)). The symbols from the transmit processor 264 may be precoded by a TX MIMO processor 266 if applicable, further processed by the modulators (MODs) in transceivers 254a-254r (e.g., for single-carrier frequency division multiplexing (SC-FDM), etc.), and transmitted to the BS 110a. At the BS 110a, the uplink signals from the UE 120a may be received by the antennas 234, processed by the demodulators in transceivers 232a-232t, detected by a MIMO detector 236 if applicable, and further processed by a receive processor 238 to obtain decoded data and control information sent by the UE 120a. The receive processor 238 may provide the decoded data to a data sink 239 and the decoded control information to the controller/processor 240.

The memories 242 and 282 may store data and program codes for BS 110a and UE 120a, respectively. The memories 242 and 282 may also interface with the controllers/processors 240 and 280, respectively. A scheduler 244 may schedule UEs for data transmission on the downlink and/or uplink.

Antennas 252, processors 258, 264, 266, and/or controller/processor 280 of the UE 120a and/or antennas 234, processors 220, 230, 238, and/or controller/processor 240 of the BS 110a may be used to perform the various techniques and methods described herein.

In certain aspects of the present disclosure, the transceivers 232 and/or the transceivers 254 may include an amplification circuit. The amplification circuit may include an amplifier and a shunt resistive element coupled between an inverting input of the amplifier (e.g., virtual ground) and a reference potential node (e.g., electrical ground) for the amplification circuit.

NR may utilize orthogonal frequency division multiplexing (OFDM) with a cyclic prefix (CP) on the uplink and downlink. NR may support half-duplex operation using time division duplexing (TDD). OFDM and single-carrier frequency division multiplexing (SC-FDM) partition the system bandwidth into multiple orthogonal subcarriers, which are also commonly referred to as tones, bins, etc. Each subcarrier may be modulated with data. Modulation symbols may be sent in the frequency domain with OFDM and in the time domain with SC-FDM. The spacing between adjacent subcarriers may be fixed, and the total number of subcarriers may be dependent on the system bandwidth. The system bandwidth may also be partitioned into subbands. For example, a subband may cover multiple resource blocks (RBs).

### Example RF Transceiver

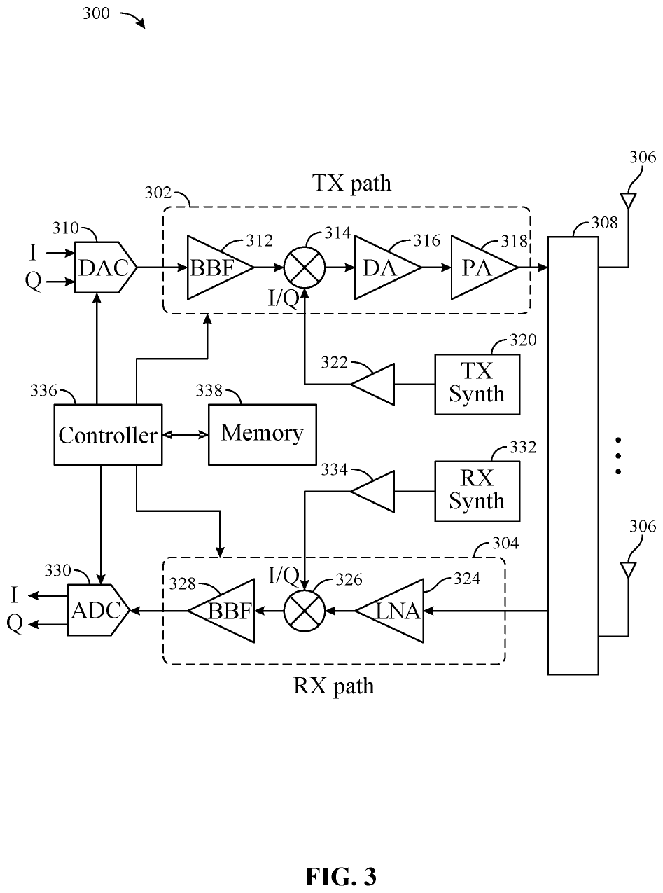

FIG. 3 is a block diagram of an example radio frequency (RF) transceiver circuit 300, in accordance with certain aspects of the present disclosure. The RF transceiver circuit 300 includes at least one transmit (TX) path 302 (also known as a “transmit chain”) for transmitting signals via one or more antennas 306 and at least one receive (RX) path 304 (also known as a “receive chain”) for receiving signals via the antennas 306. When the TX path 302 and the RX path 304 share an antenna 306, the paths may be connected with the antenna via an interface 308, which may include any of various suitable RF devices, such as a switch, a duplexer, a diplexer, a multiplexer, and the like.

Receiving in-phase (I) and/or quadrature (Q) baseband analog signals from a digital-to-analog converter (DAC) 310, the TX path 302 may include a baseband filter (BBF) 312, a mixer 314, a driver amplifier (DA) 316, and a power amplifier (PA) 318. The BBF 312, the mixer 314, the DA 316, and the PA 318 may be included in a radio frequency integrated circuit (RFIC). For certain aspects, the PA 318 may be external to the RFIC. In such aspects, the RFIC (and thus the DA 316) may be coupled to the PA 318 over one or more interconnections, for example, a conductive line or cabling such as a coaxial cable or flex circuit.

The BBF 312 filters the baseband signals received from the DAC 310, and the mixer 314 mixes the filtered baseband signals with a transmit local oscillator (LO) signal to convert the baseband signal of interest to a different frequency (e.g., upconvert from baseband to a radio frequency). This frequency-conversion process produces the sum and difference frequencies between the LO frequency and the frequencies of the baseband signal of interest. The sum and difference frequencies are referred to as the “beat frequencies.” The beat frequencies are typically in the RF range, such that the signals output by the mixer 314 are typically RF signals, which may be amplified by the DA 316 and/or by the PA 318 before transmission by the antenna(s) 306. While one mixer 314 is illustrated, several mixers may be used to upconvert the filtered baseband signals to one or more intermediate frequencies and to thereafter upconvert the intermediate frequency (IF) signals to a frequency for transmission.

The RX path 304 may include a low noise amplifier (LNA) 324, a mixer 326, and a baseband filter (BBF) 328. The LNA 324, the mixer 326, and the BBF 328 may be included in one or more RFICs, which may or may not be the same RFIC that includes the TX path components. RF signals received via the antenna(s) 306 may be amplified by the LNA 324, and the mixer 326 mixes the amplified RF signals with a receive local oscillator (LO) signal to convert the RF signal of interest to a different baseband frequency (e.g., downconvert). The baseband signals output by the mixer 326 may be filtered by the BBF 328 before being converted by an analog-to-digital converter (ADC) 330 to digital I and/or Q signals for digital signal processing.

Certain transceivers may employ frequency synthesizers with a variable-frequency oscillator (e.g., a voltage-controlled oscillator (VCO) or a digitally controlled oscillator (DCO)) to generate a stable, tunable LO with a particular tuning range. Thus, the transmit LO may be produced by a TX frequency synthesizer 320, which may be buffered or amplified by amplifier 322 before being mixed with the baseband signals in the mixer 314. Similarly, the receive LO may be produced by an RX frequency synthesizer 332, which may be buffered or amplified by amplifier 334 before being mixed with the RF signals in the mixer 326. For certain aspects, a single frequency synthesizer may be used for both the TX path 302 and the RX path 304. In certain aspects, the TX frequency synthesizer 320 and/or RX frequency synthesizer 332 may include a frequency multiplier, such as a frequency doubler, that is driven by an oscillator (e.g., a VCO) in the frequency synthesizer.

A controller 336 (e.g., controller/processor 280 in FIG. 2) may direct the operation of the RF transceiver circuit 300, such as transmitting signals via the TX path 302 and/or receiving signals via the RX path 304. The controller 336 may be a processor, a digital signal processor (DSP), an application-specific integrated circuit (ASIC), a field-programmable gate array (FPGA) or other programmable logic device (PLD), discrete gate or transistor logic, discrete hardware components, or any combination thereof. A memory 338 (e.g., memory 282 in FIG. 2) may store data and/or program codes for operating the RF transceiver circuit 300. The controller 336 and/or the memory 338 may include control logic (e.g., complementary metal-oxide-semiconductor (CMOS) logic).

For certain aspects, the RF transceiver circuit 300 may include an envelope tracking power supply that may be implemented, in part, with an amplification circuit that includes an amplifier (e.g., transimpedance amplifier) and a shunt resistive element coupled between an inverting input of the amplifier (e.g., virtual ground) and a reference potential node (e.g., ground) for the amplification circuit, as described in greater detail herein. The envelope tracking power supply may drive the power supply of the PA 318. For example, the envelope tracking power supply may modulate the power supplied to the PA 318, where the voltage associated with the modulated power supply for the PA 318 tracks (or is otherwise based on) the envelope (e.g., envelope waveform) of the signal to be amplified by the PA 318.

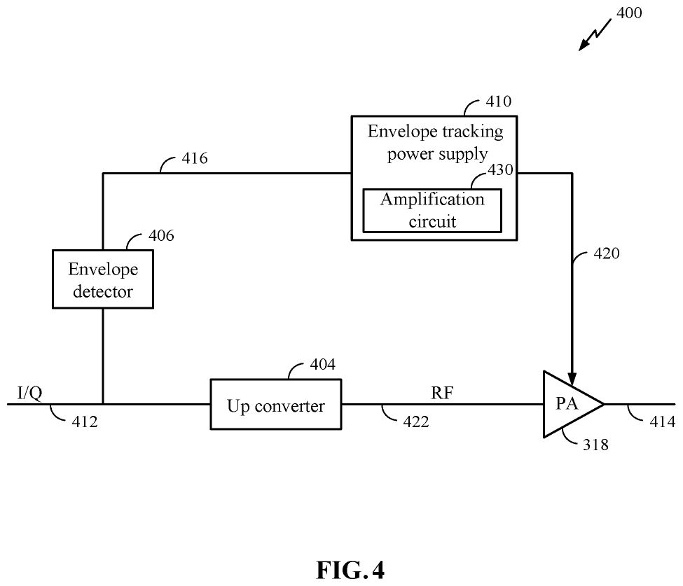

FIG. 4 illustrates an example envelope tracking amplification system 400, in which aspects of the present disclosure may be practiced. The envelope tracking amplification system 400 may include a PA 318, an upconverter 404, an envelope detector 406, and an envelope tracking power supply 410. As illustrated, the PA 318 may be configured to amplify an input signal 412 (or a signal based on the input signal). The input signal 412 may represent an in-phase (I) and/or quadrature (Q) signal. In some cases, the input signal 412 may be upconverted to an RF input signal 422 by the upconverter 404 before being amplified by the PA 318.

The input signal 412 is also used as an input to the envelope detector 406, which generates an envelope signal representing the envelope of the input signal 412 at its output 416 (e.g., provides a signal representing the magnitude of the input signal 412). The output 416 of the envelope detector 406 provides an input to the envelope tracking power supply 410, which in dependence thereon provides a supply voltage 420 to the PA 318. In this manner, the supply voltage 420 of the PA is adjusted based on (e.g., tracks) the envelope of the input signal 412. The PA 318 amplifies the input signal 412 or the RF input signal 422 to generate an amplified output signal 414 for transmission by an antenna. The PA 318 may be implemented as a single stage or multi-stage amplifier.

In certain aspects, the envelope tracking power supply 410 may include an amplification circuit 430, which includes an amplifier (e.g., transimpedance amplifier) and a shunt resistive element coupled between an inverting input of the amplifier (e.g., virtual ground) and a reference potential node (e.g., ground) for the amplification circuit 430, as described in greater detail herein.

While FIGS. 1-4 provide wireless communications as an example application in which certain aspects of the present disclosure may be implemented to facilitate understanding, certain aspects described herein may be used for amplifier circuits in any of various other suitable systems (e.g., an audio system or other electronic system).

Example Transimpedance Amplifier with Virtual Ground Shunt Resistor

Many circuit systems may use transimpedance amplifiers as one example architecture for high performance amplifiers. As a reference example, many envelope tracking amplification systems may implement class-AB type or class-G type transimpedance amplifiers. One challenge with implementing class-AB/class-G type transimpedance amplifiers in an envelope tracking amplification system is that it can be difficult to maintain the stability of the amplifier as bandwidth and output power increase. For example, class-AB/class-G amplifiers may be implemented with a low output impedance in addition to large bandwidth (e.g., >20 megahertz (MHz)). However, implementing such a low output impedance may involve using multiple stages to achieve a large open loop gain, resulting in multiple poles. In addition, class-AB/class-G amplifiers may be implemented with very large size power stages in order to support high load currents, which may result in parasitic poles moving to lower frequencies. This in turn results in either reduced bandwidth and/or reduced amplifier stability.

In certain cases, the stability of class-AB/class-G amplifiers can be improved by (i) eliminating parasitic poles and/or moving parasitic poles to higher frequencies and/or (ii) adding zeros. Eliminating/moving parasitic poles, however, can become impracticable and/or cost a lot of power when the bandwidth is at high frequencies and/or the amplifier is constructed using low-cost fabrication processes (with larger channel lengths), this can degrade efficiency of the envelope tracking amplification system. Additionally, adding zeros can also involve using large capacitors and increased power consumption, which can add to the cost of the envelope tracking amplification system and/or degrade efficiency of the envelope tracking amplification system.

Another challenge with implementing class-AB/class-G amplifiers in an envelope tracking amplification system is that the linearity of the amplifier can degrade as the bandwidth and output power targets increase, which in turn can impact the noise and tracking error of the envelope tracking amplification system.

To address the aforementioned technical challenges, certain aspects herein describe an amplification circuit that is implemented, in part, with an amplifier (e.g., transimpedance amplifier) and a shunt resistive element coupled between an inverting input of the amplifier (e.g., virtual ground) and a reference potential node (e.g., ground) for the amplification circuit. As described below, in certain aspects, the amplification circuit may also include a current source that is coupled between the shunt resistive element and a power supply node for the amplification circuit. In other aspects described herein, the amplification circuit may additionally or alternatively (to the current source) include a capacitive element coupled in series with the shunt resistive element.

Implementing the amplification circuit described herein with an amplifier and a shunt resistive element coupled between the inverting input of the amplifier and the reference potential node for the amplification circuit may improve stability and/or linearity of the amplifier, relative to conventional amplification circuits implemented without a shunt resistive element. Note that while certain examples described herein use an envelope tracking amplification system as a reference example of a system in which the amplification circuit described herein can be implemented, the amplification circuit described herein is not limited to envelope tracking amplification systems and can be used in any of various other suitable systems.

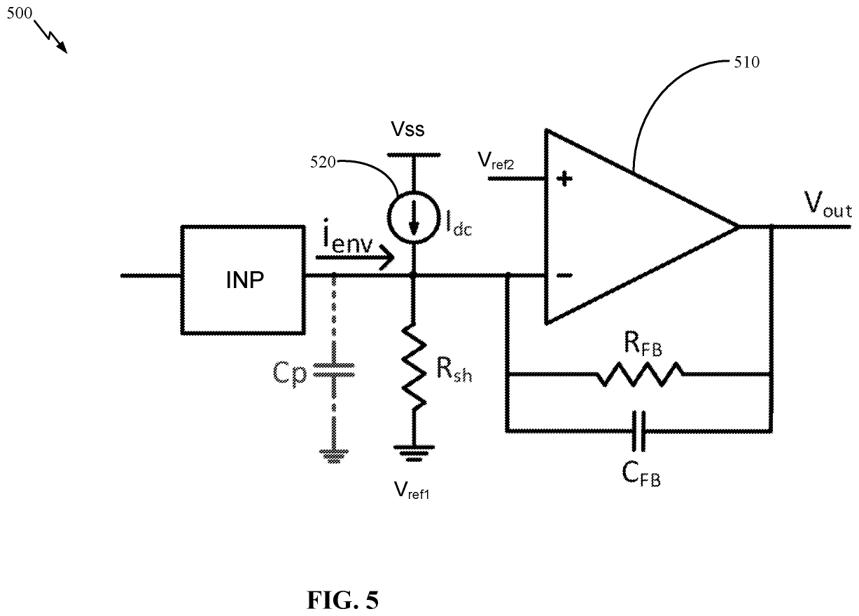

FIG. 5 illustrates an example amplification circuit 500 that may be used to amplify signals (e.g., current signals in envelope tracking applications), in accordance with certain aspects of the present disclosure. In certain aspects, the amplification circuit 500 may be used to implement the amplification circuit 430 of FIG. 4.

As shown, the amplification circuit 500 includes, without limitation, an amplifier 510, a resistive element R_{FB}, and a capacitive element C_{FB}. In certain aspects, the amplification circuit 500 implements a transimpedance amplifier with amplifier 510, resistive element R_{FB}, and capacitive element C_{FB}. Here, for example, the amplification circuit 500 includes an impedance (e.g., resistive element R_{FB} in parallel with capacitive element C_{FB}) coupled between the inverting input of the amplifier 510 and an output (Vₒᵤₜ) of the amplifier 510. The non-inverting input of the amplifier 510 is coupled to a voltage reference node (V_{ref2}). The inverting input of the amplifier 510 is configured to receive a signal (Iₑₙᵥ) from an input (INP). The amplifier 510 may include a class-AB output stage or class-G output stage.

In certain aspects, the amplification circuit 500 may also include a resistive element Rₛₕ coupled between the inverting input of the amplifier 510 and a reference potential node (V_{ref1}) for the amplification circuit 500. Here, the resistive element Rₛₕ may function as a shunt resistor since the resistive element Rₛₕ is coupled between the inverting input of the amplifier 510 (e.g., virtual ground) and the reference potential node (V_{ref1}).

In certain aspects, the amplification circuit 500 may also include a fixed or programmable direct current (DC) current source 520 coupled between a power supply node (Vₛₛ) and the resistive element Rₛₕ. In certain aspects, the power supply node (Vₛₛ) may be a low voltage supply node. For example, the power supply node (Vₛₛ) may have a lower power supply voltage than another power supply node or input of the amplifier 510. The DC current source 520 may provide DC current (I_{dc}) to compensate for DC current flowing through the resistive element Rₛₕ.

Based on a circuit analysis of the amplification circuit 500, the resistive element Rₛₕ may not divert current away from input (INP). For example, from an alternating current (AC) perspective, AC current from input (INP) may not flow through the resistive element Rₛₕ because the AC voltage at the inverting input of the amplifier 510 (e.g., virtual ground) is approximately zero. That is, because the inverting input of the amplifier 510 is at virtual ground, the input (INP) effectively sources current into virtual ground. Similarly, from a DC perspective, the DC current (I_{dc}) may compensate for DC current flowing through resistive element Rₛₕ. As noted, the DC current (I_{dc}) may be relatively small and from a low voltage supply (Vₛₛ).

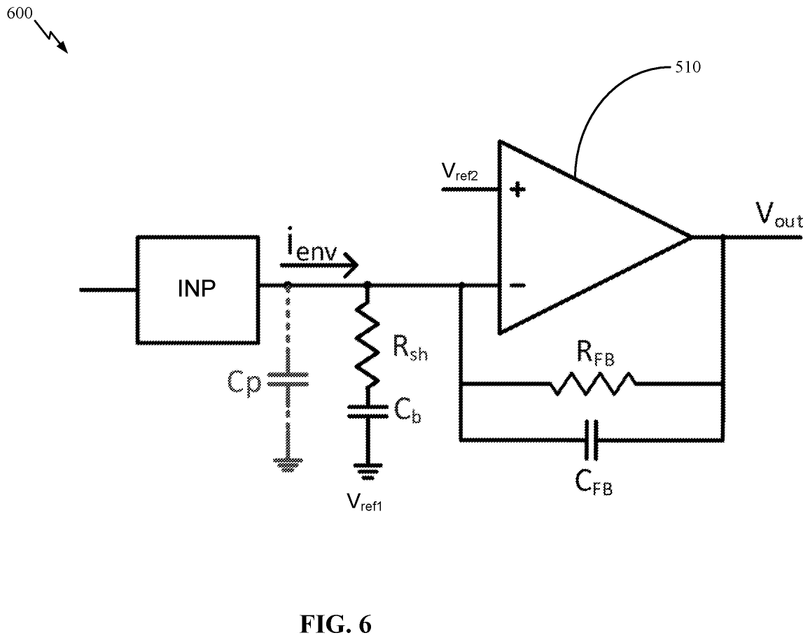

FIG. 6 illustrates another example amplification circuit 600 that may be used to amplify signals (e.g., current signals), in accordance with certain aspects of the present disclosure. In certain aspects, the amplification circuit 600 may be used to implement the amplification circuit 430 of FIG. 4.

Similar to the amplification circuit 500, the amplification circuit 600 implements a transimpedance amplifier with amplifier 510, resistive element R_{FB}, and capacitive element C_{FB}. For example, the amplification circuit 600 includes an impedance (e.g., resistive element R_{FB} in parallel with capacitive element C_{FB}) coupled between the inverting input of the amplifier 510 and an output (Vₒᵤₜ) of the amplifier 510. The non-inverting input of the amplifier 510 is coupled to a voltage reference node (V_{ref2}), and the inverting input of the amplifier 510 is configured to receive a signal (Iₑₙᵥ) from an input (INP). The amplifier 510 may include a class-AB output stage or class-G output stage.

Similar to the amplification circuit 500, the amplification circuit 600 also includes a resistive element Rₛₕ coupled between the inverting input of the amplifier 510 and a reference potential node (V_{ref1}) for the amplification circuit 500. Here, similar to the amplification circuit 500, the resistive element Rₛₕ functions as a shunt resistor.

Compared to the amplification circuit 500, in certain aspects, the amplification circuit 600 may include a DC blocking capacitive element C_{b} coupled in series between the resistive element Rₛₕ and the reference potential node (V_{ref1}). In certain aspects, adding the DC blocking capacitive element C_{b} may allow for implementing the amplification circuit 600 without a DC current source, such as DC current source 520, at the cost of capacitor area. Additionally, in certain aspects, adding the DC blocking capacitive element C_{b} in series with the resistive element Rₛₕ may decrease noise at low frequencies.

Note, in some cases, the amplification circuit 500 may be susceptible to parasitic capacitance (e.g., represented by parasitic capacitive element Cₚ) at the inverting input of the amplifier 510 of amplification circuit 500. Similarly, the amplification circuit 600 may be susceptible to parasitic capacitance (e.g., represented by parasitic capacitive element Cₚ) at the inverting input of the amplifier 510 of the amplification circuit 600.

In certain aspects, the phase margins of the amplification circuits 500 and 600 may be based in part on the resistance value of the resistive element Rₛₕ within the respective amplification circuits 500 and 600. For example, in certain aspects, using a smaller resistance value for the resistive element Rₛₕ may decrease feedback factor β, which may be represented by the following expression:

$$\frac{{R}_{s h}}{{R}_{s h} + {R}_{f b}} \frac{1 + s {R}_{f b} {C}_{f b}}{1 + s ( {R}_{s h} ‖ {R}_{f b} ) ( {C}_{f b} + {C}_{p} )}$$

As the value of β decreases, the parasitic pole associated with the amplification circuit 500 or amplification circuit 600 may be pushed to a higher frequency, thereby improving the phase margin of the amplification circuit 500 or amplification circuit 600. In some instances, when compared to the configuration without Rₛₕ (e.g., Rₛₕ=infinity), the phase margin improvement may be greater than 40 degrees (°) for certain resistance values of the resistive element Rₛₕ.

Additionally, in certain aspects, the resistive element Rₛₕ within amplification circuits 500 and 600 may be used to improve any of the gain, the bandwidth and/or the linearity of amplifier in lieu of some of the phase margin benefit described above. This in turn can help reduce the receive-band noise (RxBN) at the output of the amplification circuits 500 and 600.

### EXAMPLE OPERATIONS

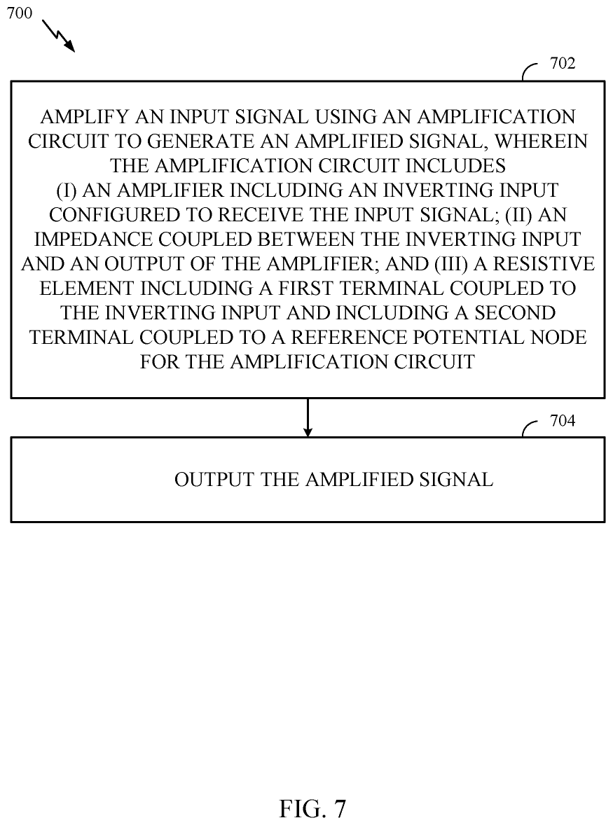

FIG. 7 is a flow diagram of example operations 700 for amplifying a signal, in accordance with certain aspects of the present disclosure. The operations 700 may be performed, for example, by an amplification circuit (e.g., amplification circuit 430, amplification circuit 500, or amplification circuit 600). In certain aspects, the amplification circuit may be a part of (and/or used to implement) an envelope tracking power supply (e.g., envelope tracking power supply 410).

The operations 700 may generally involve, at block 702, amplifying an input signal using the amplification circuit to generate an amplified signal. In certain aspects, the input signal may be received from (or based on a signal received from) a transmit path (e.g., TX path 302) of a transmitter or transceiver (e.g., transceiver 232 and/or transceiver 254). For example, the input signal (e.g., input signal 412 or output 416) may be provided as an input to an envelope tracking power supply (e.g., envelope tracking power supply 410) that includes the amplification circuit. The input signal may be a current input signal.

The operations 700 may also involve, at block 704, outputting the amplified signal. The amplified signal may be an amplified voltage signal. The amplification circuit may include (i) an amplifier (e.g., amplifier 510) that includes an inverting input configured to receive the input signal; (ii) an impedance (e.g., resistive element R_{FB} and capacitive element C_{FB}) coupled between the inverting input and an output of the amplifier (e.g., Vₒᵤₜ); and (iii) a resistive element (e.g., resistive element Rₛₕ) that includes a first terminal coupled to the inverting input and includes a second terminal coupled to a reference potential node (e.g., V_{ref1}) for the amplification circuit.

In certain aspects, the amplification circuit may further include a current source (e.g., DC current source 520) coupled between a power supply node (e.g., Vₛₛ) and the first terminal of the resistive element, e.g., as shown in FIG. 5.

In certain aspects, the amplification circuit may further include a capacitive element (e.g., DC blocking capacitive element C_{b}) coupled in series between the second terminal of the resistive element and the reference potential node for the amplification circuit, e.g., as shown in FIG. 6.

In certain aspects, the operations 700 may further involve controlling a power supply voltage of another amplifier (e.g., PA 318), based on the amplified signal.

### EXAMPLE ASPECTS

In addition to the various aspects described above, specific combinations of aspects are within the scope of the present disclosure, some of which are detailed below:

Aspect 1: An amplification circuit comprising: an amplifier including an inverting input configured to receive a signal; an impedance coupled between the inverting input and an output of the amplifier; and a resistive element including (i) a first terminal coupled to the inverting input and (ii) a second terminal coupled to a reference potential node for the amplification circuit.

Aspect 2: The amplification circuit of Aspect 1, further comprising a current source coupled between a first power supply node and the first terminal of the resistive element.

Aspect 3: The amplification circuit of Aspect 2, wherein the current source is a programmable current source.

Aspect 4: The amplification circuit of any of Aspects 2 to 3, wherein the amplifier further includes a power supply input coupled to a second power supply node and wherein the first power supply node is configured to have a lower power supply voltage than the second power supply node.

Aspect 5: The amplification circuit of Aspect 1, further comprising a capacitive element coupled in series between the second terminal of the resistive element and the reference potential node.

Aspect 6: The amplification circuit of any of Aspects 1 to 5, wherein the amplifier further includes a non-inverting input coupled to a voltage reference node.

Aspect 7: The amplification circuit of any of Aspects 1 to 6, wherein the amplifier comprises a class-AB or class-G output stage.

Aspect 8: The amplification circuit of any of Aspects 1 to 7, wherein the output of the amplifier is coupled to a power supply node of another amplifier.

Aspect 9: The amplification circuit of Aspect 8, wherein the output of the amplifier comprises a power supply voltage.

Aspect 10: A wireless device comprising: an amplification circuit comprising: a first amplifier including an inverting input configured to receive a signal; an impedance coupled between the inverting input and an output of the first amplifier; and a resistive element including (i) a first terminal coupled to the inverting input and (ii) a second terminal coupled to a reference potential node for the amplification circuit; and a second amplifier including a first power supply node coupled to an output of the amplification circuit.

Aspect 11: The wireless device of Aspect 10, wherein the amplification circuit further comprises a current source coupled between a second power supply node and the first terminal of the resistive element.

Aspect 12: The wireless device of Aspect 11, wherein the first amplifier further includes a power supply input coupled to a third power supply node and wherein the second power supply node has a lower power supply voltage than the third power supply node.

Aspect 13: The wireless device of Aspect 10, wherein the amplification circuit further comprises a capacitive element coupled in series between the second terminal of the resistive element and the reference potential node.

Aspect 14: The wireless device of any of Aspects 10 to 13, wherein the first amplifier further includes a non-inverting input coupled to a voltage reference node.

Aspect 15: The wireless device of any of Aspects 10 to 14, wherein the first amplifier comprises a class-AB or class-G output stage.

Aspect 16: The wireless device of any of Aspects 10 to 15, wherein: the amplification circuit is configured to generate a power supply voltage based on the signal; and the output of the amplification circuit comprises the power supply voltage.

Aspect 17: A method comprising: amplifying an input signal via an amplification circuit to generate an amplified signal, wherein the amplification circuit comprises (i) an amplifier including an inverting input configured to receive the input signal; (ii) an impedance coupled between the inverting input and an output of the amplifier; and (iii) a resistive element including a first terminal coupled to the inverting input and including a second terminal coupled to a reference potential node for the amplification circuit; and outputting the amplified signal.

Aspect 18: The method of Aspect 17, further comprising controlling a power supply voltage of another amplifier, based on the amplified signal.

Aspect 19: The method of any of Aspects 17 to 18, wherein the amplification circuit is a transimpedance amplification circuit.

Aspect 20: The method of any of Aspects 17 to 19, wherein the amplifier comprises a class-AB or class-G output stage.

Aspect 21: The method of any of Aspects 17 to 20, wherein the amplifier comprises a non-inverting input coupled to a voltage reference node.

### CONCLUSION

Described herein is an amplification circuit design to improve stability and linearity of amplifiers, such as class-AB amplifiers or class-G amplifiers, as illustrative, non-limiting examples. Certain aspects of the present disclosure provide an amplification circuit that includes an amplifier, an impedance coupled between an inverting input of the amplifier and an output of the amplifier, and a resistive element including (i) a first terminal coupled to the inverting input and (ii) a second terminal coupled to a reference potential node for the amplification circuit.

The above description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim. The word “exemplary” is used herein to mean “serving as an example, instance, or illustration.” Any aspect described herein as “exemplary” is not necessarily to be construed as preferred or advantageous over other aspects.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components. For example, means for amplifying an input signal may include an amplification circuit, such as the amplification circuit 430 of FIG. 4, the amplification circuit 500 of FIG. 5, or the amplification circuit 600 of FIG. 6. Means for outputting an amplified signal may include an amplification circuit, such as the amplification circuit 430 of FIG. 4, the amplification circuit 500 of FIG. 5, or the amplification circuit 600 of FIG. 6. Means for controlling a power supply voltage of another amplifier may include an amplification circuit, such as the amplification circuit 430 of FIG. 4, the amplification circuit 500 of FIG. 5, or the amplification circuit 600 of FIG. 6.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, “a processor,” “at least one processor,” or “one or more processors” generally refers to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory,” or “one or more memories” generally refers to a single memory configured to store data and/or instructions or multiple memories configured to collectively store data and/or instructions.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

1. An amplification circuit comprising:
an amplifier including an inverting input configured to receive a signal;
an impedance coupled between the inverting input and an output of the amplifier; and
a resistive element including (i) a first terminal coupled to the inverting input and (ii) a second terminal coupled to a reference potential node for the amplification circuit.

2. The amplification circuit of claim 1, further comprising a current source coupled between a first power supply node and the first terminal of the resistive element.

3. The amplification circuit of claim 2, wherein the current source is a programmable current source.

4. The amplification circuit of claim 2, wherein the amplifier further includes a power supply input coupled to a second power supply node and wherein the first power supply node is configured to have a lower power supply voltage than the second power supply node.

5. The amplification circuit of claim 1, further comprising a capacitive element coupled in series between the second terminal of the resistive element and the reference potential node.

6. The amplification circuit of claim 1, wherein the amplifier further includes a non-inverting input coupled to a voltage reference node.

7. The amplification circuit of claim 1, wherein the amplifier comprises a class-AB or class-G output stage.

8. The amplification circuit of claim 1, wherein the output of the amplifier is coupled to a power supply node of another amplifier.

9. The amplification circuit of claim 8, wherein the output of the amplifier comprises a power supply voltage.

10. A wireless device comprising:
an amplification circuit comprising:
a first amplifier including an inverting input configured to receive a signal;
an impedance coupled between the inverting input and an output of the first amplifier; and
a resistive element including (i) a first terminal coupled to the inverting input and (ii) a second terminal coupled to a reference potential node for the amplification circuit; and
a second amplifier including a first power supply node coupled to an output of the amplification circuit.

11. The wireless device of claim 10, wherein the amplification circuit further comprises a current source coupled between a second power supply node and the first terminal of the resistive element.

12. The wireless device of claim 11, wherein the first amplifier further includes a power supply input coupled to a third power supply node and wherein the second power supply node has a lower power supply voltage than the third power supply node.

13. The wireless device of claim 10, wherein the amplification circuit further comprises a capacitive element coupled in series between the second terminal of the resistive element and the reference potential node.

14. The wireless device of claim 10, wherein the first amplifier further includes a non-inverting input coupled to a voltage reference node.

15. The wireless device of claim 10, wherein the first amplifier comprises a class-AB or class-G output stage.

16. The wireless device of claim 10, wherein:
the amplification circuit is configured to generate a power supply voltage based on the signal; and
the output of the amplification circuit comprises the power supply voltage.

17. A method of wireless communication comprising:
amplifying an input signal via an amplification circuit to generate an amplified signal, wherein the amplification circuit comprises (i) an amplifier including an inverting input configured to receive the input signal; (ii) an impedance coupled between the inverting input and an output of the amplifier; and (iii) a resistive element including a first terminal coupled to the inverting input and including a second terminal coupled to a reference potential node for the amplification circuit; and
outputting the amplified signal.

18. The method of claim 17, further comprising controlling a power supply voltage of another amplifier, based on the amplified signal.

19. The method of claim 17, wherein the amplification circuit is a transimpedance amplification circuit.

20. The method of claim 17, wherein the amplifier comprises a class-AB or class-G output stage.
